(19) United States
(12) Patent Application Publication
(10) Pub. No.: US 2009/0108327 A1
(43) Pub. Date: Apr. 30, 2009

(54) Gate pattern having two control gates, flash memory including the gate pattern and methods of manufacturing and operating the same

(75) Inventors: Tae-Whan Kim, Seoul (KR); Kyeong-Rock Kim, Seoul (KR); Kae-Dal Kwack, Seoul (KR)

Correspondence Address: HARNESS, DICKEY & PIERCE, P.L.C., P.O. BOX 8910, RESTON, VA, 20195, US

(73) Assignees: SUMSUNG ELECTRONICS CO., LTD.; INDUSTRY-UNIVERSITY COOPERATION FOUNDATION HANYANG UNIVERSITY

(21) Appl. No.: 12/289,300

(22) Filed: Oct. 24, 2008

(30) Foreign Application Priority Data
Oct. 25, 2007 (KR) 10-2007-0107807

(51) Int. Cl. H01L 29/788

(52) U.S. Cl. 257/319; 257/E29.3

(57) ABSTRACT

Provided may be a gate pattern, flash memory and methods of manufacturing and operating the same. A gate pattern may include a floating gate on a tunneling dielectric layer, an inter-gate dielectric layer on the floating gate, a first control gate on the inter-gate dielectric layer, and a second control gate on the inter-gate dielectric layer and spaced apart from the first control gate. Each of the control gates sets four states according to an application time of a program voltage applied to the control gates. Thus, one control gate may program 2-bit data.

### PRIORITY STATEMENT

This application claims priority under U.S.C. §119 to Korean Patent Application No. 10-2007-0107807, filed on Oct. 25, 2007, in the Korean Intellectual Property Office (KIPO), the entire contents of which are incorporated herein by reference.

### BACKGROUND

1. Field

Example embodiments relate to a gate pattern, a flash memory including the gate pattern and methods of manufacturing and operating the same, and more particularly, to a gate pattern having a structure where gates may be separated in one memory cell, a flash memory including the gate pattern, and methods of manufacturing and operating the same.

2. Description of the Related Art

A flash memory is a representative nonvolatile memory that may be implemented with relatively high integration density and high capacity. In particular, because of improved data retention characteristics, a flash memory is considered as a next-generation memory device that may be used as the main memory within a system and may replace an existing hard disk.

### SUMMARY

Example embodiments provide a gate pattern which may be capable of storing 4 bits in one cell transistor and a flash memory including the gate pattern. Example embodiments also provide methods of manufacturing and operating the flash memory.

Example embodiments provide a gate pattern including a floating gate on a tunneling dielectric layer; an inter-gate dielectric layer on the floating gate; a first control gate on the inter-gate dielectric layer; and a second control gate on the inter-gate dielectric layer spaced apart from the first control gate. In example embodiments, the flash memory may include the gate pattern of example embodiments on a substrate; a source region in the substrate on a side of the gate pattern; and a drain region in the substrate and facing the source region with respect to the gate pattern.

In example embodiments, a method of manufacturing a flash memory may include sequentially forming a tunneling dielectric layer, a floating gate layer, an inter-gate dielectric layer, and a control gate layer on a substrate; defining a first region on the substrate, and etching the inter-gate dielectric layer and the control gate layer on the first region to expose the floating gate layer; forming an intermediate dielectric layer on the exposed surface of the floating gate layer of the first region and sides of the control gate layer; forming an intermediate gate layer on the intermediate dielectric layer; and defining a region on the intermediate gate layer and the control gate layer, and etching the intermediate gate layer and the control gate layer of the defined region to expose the surface of the substrate and form first and second control gate layers.

In example embodiments, a method of operating a flash memory may include providing a floating gate, an inter-gate dielectric layer, a first control gate, and a second control gate spaced apart from the first control gate on a tunneling dielectric layer; and applying a program voltage to the first control gate or the second control gate.

### BRIEF DESCRIPTION OF THE FIGURES

Example embodiments will be more clearly understood from the following detailed description taken in conjunction with the accompanying drawings. FIGS. 1-6 represent non-limiting, example embodiments as described herein.

FIG. 1 is a cross-sectional view illustrating a cell transistor of a flash memory;

FIG. 2 is a cross-sectional view illustrating a cell transistor of a flash memory according to example embodiments;

FIGS. 3A-3D are cross-sectional views illustrating a method of manufacturing the cell transistor of the flash memory of FIG. 2 according to example embodiments;

FIG. 4 is a layout diagram of a NAND flash memory with the cell transistors of FIG. 1 according to example embodiments;

FIG. 5 is a graph showing a charge amount trapped in the floating gate of the cell transistor of FIG. 2 with respect to a program time according to example embodiments; and

FIG. 6 is a graph showing a read operation of the cell transistor of FIGS. 2 and 3 according to example embodiments.

It should be noted that these Figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION OF EXAMPLE EMBODIMENTS

Example embodiments will be described more fully hereinafter with reference to the accompanying drawings, in which example embodiments are shown. Example embodiments may, however, be embodied in different forms and should not be construed as limited to example embodiments set forth herein. Rather, example embodiments are provided so that this disclosure will be thorough and complete, and will fully convey the scope of example embodiments to those skilled in the art. In the drawings, the thickness of layers and regions are exaggerated for clarity. Like numbers refer to like elements throughout the specification.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items.

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

In a flash memory, data storage may be achieved by changing a threshold voltage of a cell transistor. Specifically, the cell transistor may include a gate pattern configured with a tunneling dielectric layer, a floating gate, an inter-gate dielectric layer, and a control gate. A data program operation and a data erase operation of the flash memory may be achieved by Fowler-Nordheim tunneling or hot carrier injection. The program operation may be an operation that traps electrons from a substrate in the floating gate through the tunneling dielectric layer, and the erase operation may be an operation that moves the electrons trapped in the floating gate through the tunneling dielectric layer to the substrate. In order to perform the above-described operations smoothly, a voltage relatively higher than a voltage applied to the control gate should be applied to the floating gate. That is, even though the same voltage is applied to the control gate, a voltage of a high level should be applied to the floating gate by appropriate selection of dielectric layers.

Furthermore, in order to perform the program operation of trapping electrons in the floating gate and the read operation of moving the trapped electrons to the substrate, a structure where the floating gate may include silicon nitride. This is called an oxide/nitride/oxide (ONO) structure. That is, the floating gate may include nitride, and lower and upper dielectric layers are formed of oxide. Electrons passing through the tunneling dielectric layer formed of oxide may be trapped on the silicon nitride layer. That is, in case when the floating gate is formed of polycrystalline silicon, electrons may be trapped within a bulk of polycrystalline silicon.

Hereinafter, exemplary embodiments of the present invention will be described in detail with reference to the accompanying drawings.

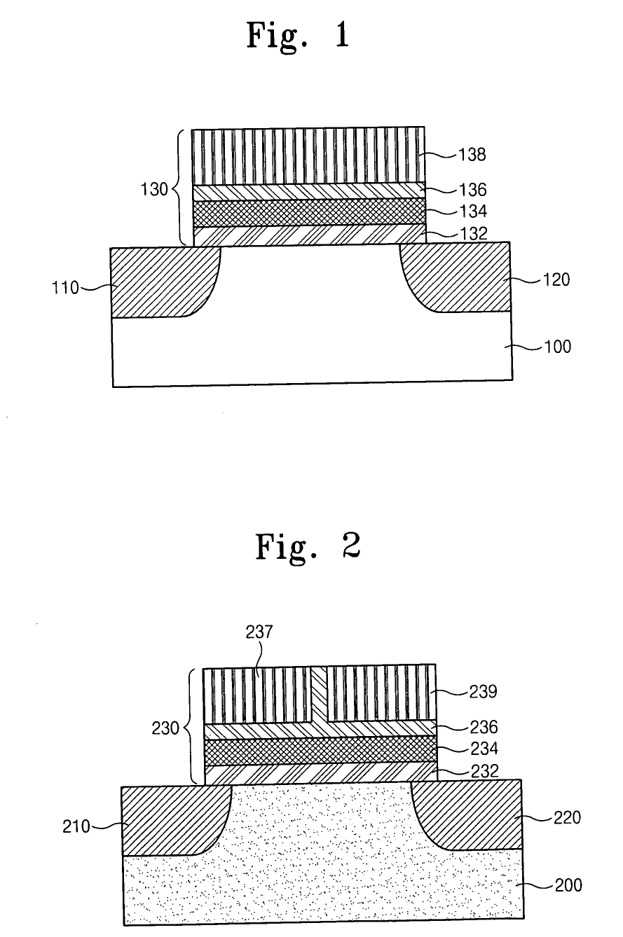

FIG. 1 is a cross-sectional view illustrating a cell transistor of a flash memory.

Referring to FIG. 1, the cell transistor may have an ONO structure. That is, a source region 110 and a drain region 120 may be defined in a substrate 100, and a gate pattern 130 may be disposed on a channel region between the source region 110 and the drain region 210.

The gate pattern 130 may include a tunneling dielectric layer 132, a floating gate 134, an inter-gate dielectric layer 136, and a control gate 138. In an ONO structure, the tunneling dielectric layer 132 and the inter-gate dielectric layer 138 may include oxide, and the floating gate 136 may include silicon nitride. In a program operation, electrons may be trapped in the floating gate 136. In an erase operation, the electrons trapped on the floating gate 136 may be transferred through the tunneling dielectric layer 132 to the substrate 100.

A threshold voltage of the cell transistor may be changed by the program operation and the erase operation. That is, information about the cell transistor may be stored by the change of the threshold voltage.

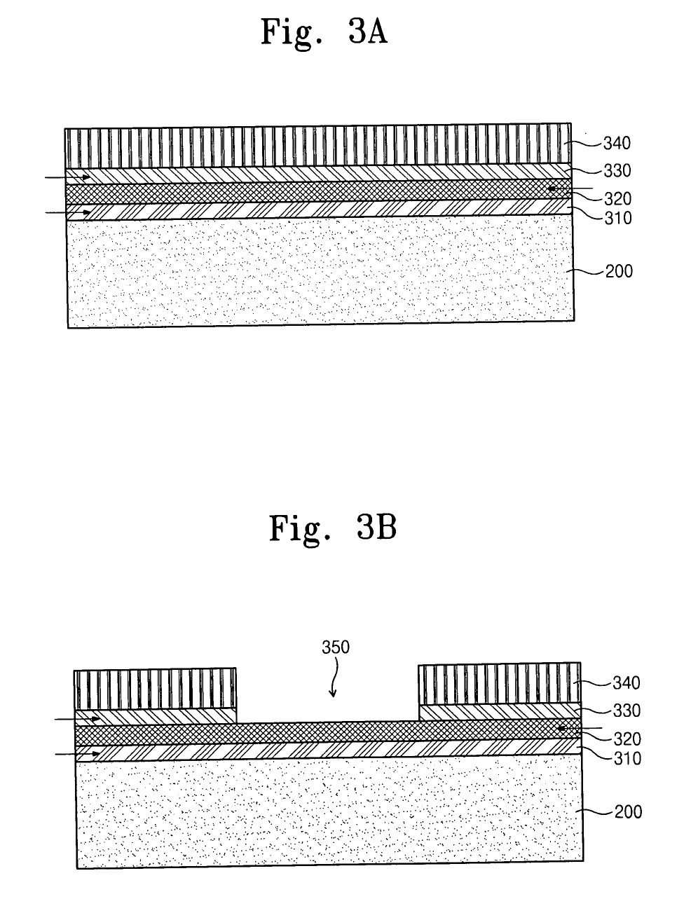

FIG. 2 is a cross-sectional view illustrating a cell transistor of a flash memory according to example embodiments. Referring to FIG. 2, a cell transistor according to example embodiments may include a source region 210, a drain region 220, and a gate pattern 230 on a substrate 200.

The gate pattern 230 may include a tunneling dielectric layer 232, a floating gate 234, an inter-gate dielectric layer 236, a first control gate 237, and a second control gate 239. The tunneling dielectric layer 232 may include silicon oxide. Therefore, the tunneling dielectric layer 232 may be formed by a thermal oxidation process. Alternatively, the tunneling dielectric layer 232 may be formed by an atomic layer deposition (ALD) process or a chemical vapor deposition (CVD) process. Where the tunneling dielectric layer 232 is formed by a thermal oxidation process, the silicon oxide layer may be formed by injecting hydrogen and oxygen into a chamber and oxidizing silicon of the substrate under predetermined or given pressure and temperature conditions.

The floating gate 234 may be disposed on the tunneling dielectric layer 232. The floating gate 234 may include silicon nitride. The inter-gate dielectric layer 236 may be disposed on the floating gate 234. The inter-gate dielectric layer 236 may include silicon oxide or metal oxide. Specifically, the metal oxide may include hafnium oxide, titanium oxide, yttrium oxide, aluminum oxide, tantalum oxide, zirconium oxide, or a combination thereof. Alternatively, nitrogen or silicon may be added to hafnium oxide, titanium oxide, yttrium oxide, aluminum oxide, tantalum oxide, or zirconium oxide.

The first control gate 237 and the second gate control gate 239 may be disposed on the inter-gate dielectric layer 236. In addition, the first control gate 237 and the second gate control gate 239 may be spaced apart from each other, and a space between the first control gate 237 and the second control gate 239 may be filled with the inter-gate dielectric layer 236.

The first control gate 237 and the second control gate 239 may include polycrystalline silicon, metal, conductive metal nitride, or conductive oxide. The first control gate 237 and the second control gate 239 may include polycrystalline silicon. Furthermore, although not illustrated in FIG. 2, sidewall spacers formed of nitride may be further disposed on sidewalls of the gate pattern 230.

In FIG. 2, 2-bit data may be programmed to the cell transistor with respect to a program time during which a program voltage is applied to the first control gate 237. Alternatively, 2-bit data may be programmed to the cell transistor with respect to a program time during which a program voltage is applied to the second control gate 239. Therefore, where the data programmed through the first control gate 237 is set as upper bits and the data programmed through the second control gate 239 is set as lower bits, one cell transistor may store 4-bit data.

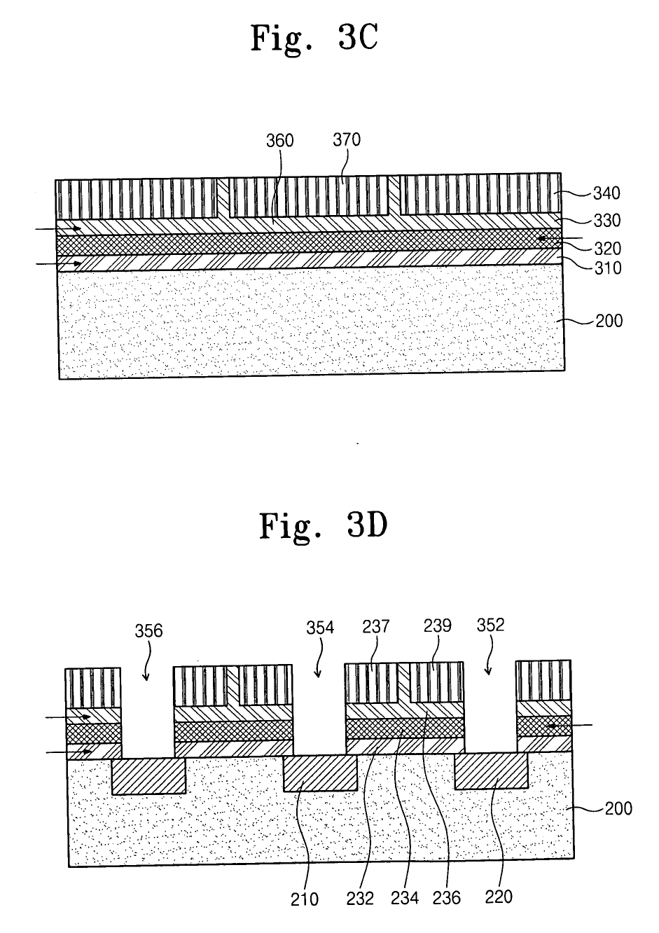

FIGS. 3A-3D are cross-sectional views illustrating a method of manufacturing the cell transistor of the flash memory of FIG. 2 according to example embodiments. Referring to FIG. 3A, a tunneling dielectric layer 310, a floating gate layer 320, an inter-gate dielectric layer 330, and a control gate layer 240 may be sequentially formed on a substrate 200. The substrate 200 may be p-type in order to prepare for the n+ doping of a source region and a drain region, which will be formed later.

The tunneling dielectric layer 310 on the substrate 200 may be formed by a CVD process, an ALD process, or a thermal oxidation process, e.g., a thermal oxidation process. The thermal oxidation process is a process that oxidizes silicon of the substrate by supplying hydrogen and oxygen into the chamber. The tunneling dielectric layer 310 may be formed of silicon oxide by the thermal oxidation process. A floating gate layer 320 may be formed on the tunneling dielectric layer 310. The floating gate layer 320 may include silicon nitride.

An inter-gate dielectric layer 330 may be formed on the floating gate layer 320. The inter-gate dielectric layer 330 may include silicon oxide or metal oxide. Where the inter-gate dielectric layer 330 includes metal oxide, the metal oxide may include hafnium oxide, titanium oxide, yttrium oxide, aluminum oxide, tantalum oxide, zirconium oxide, or a combination thereof. Alternatively, nitrogen or silicon may be added to hafnium oxide, titanium oxide, yttrium oxide, aluminum oxide, tantalum oxide, or zirconium oxide. The metal oxide allows for the inter-gate dielectric layer 330 to have a relatively high dielectric constant. A control gate layer 340 may be formed on the inter-gate dielectric layer 330. The control gate layer 340 may include polycrystalline silicon, metal, conductive metal nitride, or conductive oxide. The control gate layer 340 may include polycrystalline silicon.

Referring to FIG. 3B, a photoresist (not shown) may be coated over the substrate 200 where the control gate layer 340 is formed, and a photoresist pattern may be formed by a photolithography process to open an upper portion of a first region 350. Using the photoresist pattern as an etch mask, an etching process may be performed on the opened upper portion of the first region 350. The etching process may be an anisotropic dry etching process. In addition, an etchant used in the etching process may be any material having an etch selectivity between a material of the floating gate layer 320 and a material of the inter-gate dielectric layer 330. Therefore, the floating gate layer 320 may be exposed through the first region 350 by the etching process.

Referring to FIG. 3C, an intermediate dielectric layer 360 may be coated on the floating gate layer 320, which is exposed through the first region 350, and the control gate layer 340 disposed on both sides of the floating gate layer 320. The intermediate dielectric layer 360 may be formed of the same material as the inter-gate dielectric layer 330. Thereafter, the intermediate dielectric layer 360 coated on the control gate layer 340 may be removed. The process of removing the intermediate dielectric layer 360 may be performed by a chemical mechanical polishing (CMP) process. Due to the removal of the inter-layer dielectric layer formed on the control gate layer 340, the intermediate dielectric layer 360 may remain only on the upper portion of the floating gate layer 320 of the first region 350 and both sidewalls of the control gate layer 340. An intermediate gate layer 370 may be formed to fill the opened first region 350 where the intermediate dielectric layer 360 remains. The interlayer gate layer 370 may be formed of the same material as the adjacent control gate layer 340.

Referring to FIG. 3D, a photoresist (not shown) may be coated on the intermediate gate layer 370 and the control gate layer 340 as illustrated in FIG. 3C, and a photolithography process may be performed to form a photoresist pattern (not shown) defining a second region 352, a third region 354, and a fourth region 356.

Thereafter, an etching process may be performed using the photoresist pattern as an etch mask. The etching process may be an anisotropic dry etching process. The etching process may be performed to expose the surface of the substrate 200 disposed under the second region 352, the third region 354, and the fourth region 356. Therefore, the second region 352, the third region 354, and the fourth region 356 may be opened to expose the surface of the substrate 200. In addition, due to the etching process, a tunneling dielectric layer 232, a floating gate 234, an inter-gate dielectric layer 236, a first control gate 237, and a second control gate 239 of a cell transistor may be formed. Furthermore, the first control gate 237 and the second control gate 239 may be spaced apart from each other, and a space between the first control gate 237 and the second control gate 239 may be filled with the inter-gate dielectric layer 236.

Although not shown, sidewall spacers may be formed to enclose sidewalls of the gate pattern of the cell transistor. A source region 210 and a drain region 220 may be formed by performing an ion implantation process on the substrate where the cell transistor is formed. Through the above-described processes, a plurality of cell transistors may be formed.

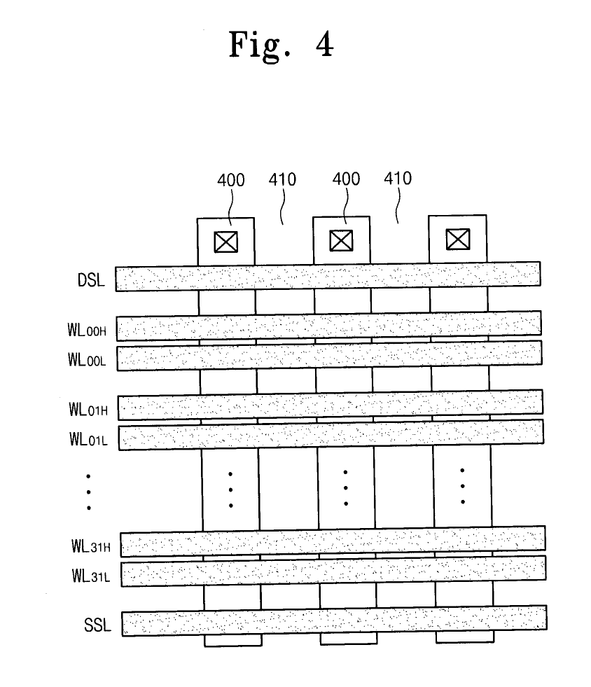

FIG. 4 is a layout diagram of a NAND flash memory with the cell transistors of FIG. 1 according to example embodiments. Referring to FIG. 4, a shallow device isolation layer 410 may be disposed to isolate active regions 400. A plurality of cell transistors may be provided in the active regions 400. Each of the cell transistors may include a plurality of word lines WL_{00H}, WL_{00L}, . . . , WL_{31H} and WL_{31L} serving as two control gates. For convenience, elements other than two word lines of the cell transistor may be omitted in FIG. 4. The two word lines of the cell transistor correspond to the first control gate and the second control gate of FIG. 2.

In FIG. 4, the first word lines may include the first uppermost word line WL_{00H} and the first lowermost word line WL_{00L}. These word lines may be arranged orderly from the thirty-second uppermost word line WL_{31H} and the thirty-second lowermost word line WL_{31L}. The word lines WL_{00H}, WL_{00L}, . . . , WL_{31H} and WL_{31L} may be formed across the active regions 400 arranged in parallel.

Furthermore, a drain select line DSL may be disposed on the first word lines WL00H and WL_{00L}. Although not shown in FIG. 4, the drain select line DSL may control an on/off operation of a drain select transistor. In addition, a source select line SSL may be disposed under the thirty-second word lines WL_{31H} and WL_{31L} which may be the last of the word lines. Although not shown in FIG. 4, the source select line SSL may control an on/off operation of a source select transistor. In the above-described NAND flash memory, one cell transistor may be controlled by the uppermost word line and the lowermost word line corresponding to the two control gates.

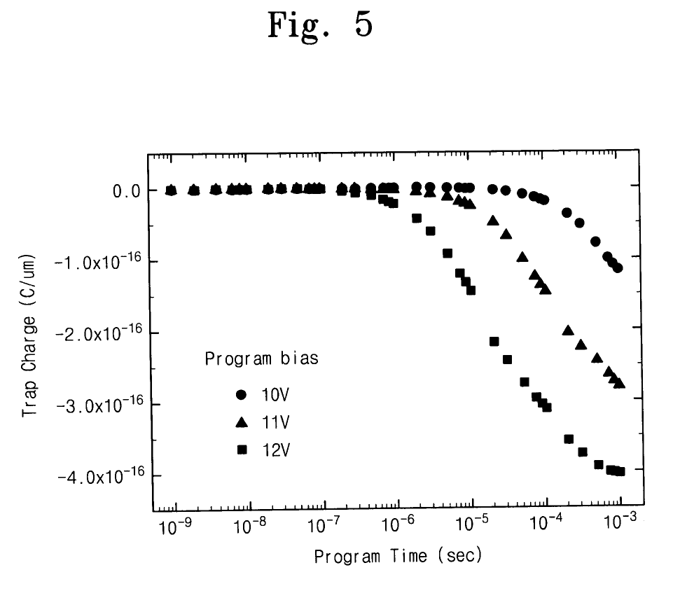

FIG. 5 is a graph showing a charge amount trapped in the floating gate of the cell transistor of FIG. 2 with respect to a program time according to example embodiments. The graph of FIG. 5 was obtained under specific physical property conditions and a specific thickness of the gate structure in the cell transistor of FIG. 2. For example, the tunneling dielectric layer may include silicon oxide and may be about 5 nm thick, and the floating gate may include silicon nitride and may be about 4 nm thick. Also, the inter-gate dielectric layer may include silicon oxide and may be about 8 nm thick, and the first control gate and the second control gate may include polycrystalline silicon and may be about 50 nm thick.

Referring to FIG. 5, a program voltage may be applied to one of the two control gates. As time passes by, the quantity of electrons trapped on the floating gate may increase. Furthermore, as the program voltage applied to the selected control gate increases, the electrons may be trapped on the floating gate more rapidly. Where the program voltage is constant and the program time is adjusted, a plurality of states may be set through one gate. According to example embodiments, four states may be implemented by controlling the program time during which the program voltage is applied to one gate. For example, a state “11” represents a state where no or few electrons exist on the floating gate because a program operation may be performed for a relatively short time, or an erased state may be maintained without performing the program operation; a state “10” represents a state where a first charge amount may be trapped on the floating gate; a state “01” represents a state where a second charge amount more than the first charge amount may be trapped on the floating gate; and a state “00” represents a state where a third charge amount more than the second charge amount may be trapped on the floating gate over a sufficient program time.

The states “00”, “01”, “10” and “11” and the trapped charge amount may be variously changed. According to the program time, four states may be set and one control gate may program 2-bit data according to the set states. For example, four states may be implemented through the application time of the program voltage applied to one of the two control gates. 2-bit data may be programmed through one control gate.

Therefore, the cell transistor having two control gates according to example embodiments may program and store 4-bit data. For example, as illustrated in FIG. 3, when the word lines corresponding to the control gate are separately arranged as the uppermost word line and the lowermost word line, 4-bit data may be programmed through one cell transistor.

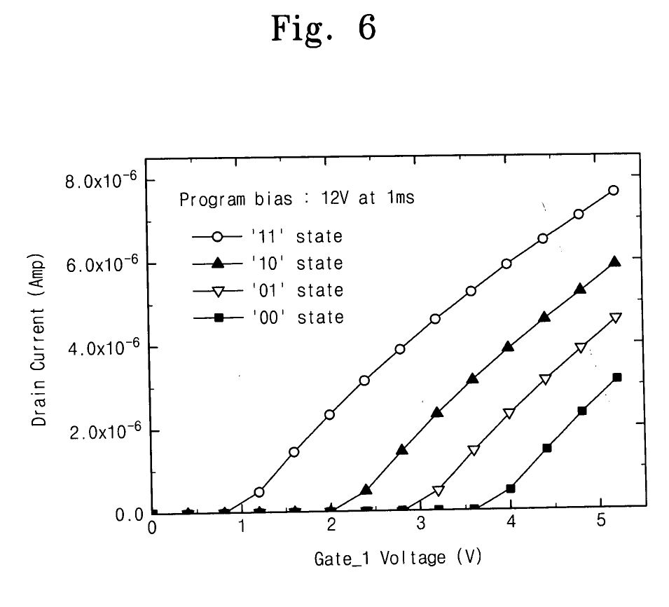

FIG. 6 is a graph showing a read operation of the cell transistor of FIGS. 2 and 3 according to example embodiments. The characteristic graph of FIG. 6 was obtained from the cell transistor having the same conditions and structure as those of FIG. 5. Referring to FIG. 6, four states may be implemented through one control gate by using the program voltage of about 12 V. For example, the states “00”, “01”, “10” and “11” may be implemented.

In the read operation, a turn-on voltage may be applied to the drain select line and the source select line illustrated in FIG. 3. Therefore, a positive power supply voltage VDD may be applied to the cell transistor having the first uppermost word line and the first lowermost word line, and a ground voltage may be applied to the cell transistor having the thirty-second uppermost word line and the thirty-second lowermost word line. When the read operation is performed on data programmed in a specific transistor, all transistors other than the selected transistor may be turned on. In addition, a predetermined or given read voltage may be applied to the control gate of the selected transistor. Because a drain current is varied according to the programmed state of the selected transistor, the programmed data may be read by the drain current.

In FIG. 6, the program voltage was about 12 V, and the drain current with respect to the voltage of the control gate was measured according to the set states. In FIG. 6, when the read voltage applied to the control gate may be about 2.8 V or higher, no current flows in the state “00”, and a different amount of current flows in the other states. Therefore, it may be preferable to apply the read voltage of about 2.8 V or higher to the cell transistor exhibiting the characteristic of FIG. 6.

However, the read operation of the above-described cell transistor may be implemented in various methods. Furthermore, the read operation may be performed two times on the selected cell transistors. For example, when reading data programmed in the cell transistor controlled by the second uppermost word line and the second lowermost word line in FIG. 3, the other cell transistors may be turned on.

First, the voltage applied to the second lowermost word line may be made not to affect the drain current by applying the read voltage to the second uppermost word line and maintaining the second lowermost word line at the floating level or about 0 V or less. By floating the second lowermost word line, the influence of the second lowermost word line may be completely removed. Data programmed with 2 bits may be read according to the read voltage applied to the second uppermost word line. Using the same principle, the read voltage may be applied to the second lowermost word line, and the read operation may be performed on 2 bits corresponding to the lower bits.

According to the above-described structure and operation, 4-bit data may be programmed in one cell transistor, and the read operation on the 4-bit data may be performed at least two times. Therefore, a relatively large quantity of data may be stored in a relatively small area, and the read operation may be performed on the stored data at a relatively high speed.

Furthermore, because the floating gate is formed of silicon nitride, electrons trapped on the silicon nitride may have a lower mobility. For example, because electrons in the floating gate has a relatively low mobility compared to the case where the floating gate is formed of polycrystalline silicon or metal which may be a conductive material, the electrons trapped by the first control gate may not influence the operation of the second control gate. Because the first control gate and the second control gate are spaced apart from each other and the space therebetween may be filled with the nonconductive inter-gate dielectric layer, the influence of the two control gates may be minimized or reduced. Therefore, the program and erase operations may be independently performed on the same channel region and floating gates.

According to example embodiments, one cell transistor may include two separate control gates. Thus, one cell transistor may store 4-bit data, and a read operation on the 4-bit data may be performed at least two times. Therefore, more data may be stored in one cell in the same cell area. Furthermore, the read operation may be performed at a higher speed.

The above-disclosed subject matter may be to be considered illustrative, and not restrictive, and the appended claims may be intended to cover all such modifications, enhancements, and other embodiments, which fall within the true spirit and scope of example embodiments. Thus, to the maximum extent allowed by law, the scope of example embodiments may be to be determined by the broadest permissible interpretation of the following claims and their equivalents, and shall not be restricted or limited by the foregoing detailed description.

1. A gate pattern comprising:
a floating gate on a tunneling dielectric layer;
an inter-gate dielectric layer on the floating gate;
a first control gate on the inter-gate dielectric layer; and
a second control gate on the inter-gate dielectric layer spaced apart from the first control gate.

2. The gate pattern of claim 1, wherein a space between the first control gate and the second control gate is filled with the inter-gate dielectric layer.

3. The gate pattern of claim 1, wherein the tunneling dielectric layer includes silicon oxide.

4. The gate pattern of claim 1, wherein the floating gate includes silicon nitride, and electrons are trapped on the floating gate during a program operation.

5. The gate pattern of claim 1, wherein the inter-gate dielectric layer includes silicon oxide or metal oxide.

6. The gate pattern of claim 5, wherein the metal oxide includes hafnium oxide, titanium oxide, yttrium oxide, aluminum oxide, tantalum oxide, zirconium oxide, or a combination thereof.

7. The gate pattern of claim 6, wherein the metal oxide further includes nitrogen or silicon.

8. The gate pattern of claim 1, wherein the first control gate and the second control gate includes polycrystalline silicon, metal, conductive metal nitride, or conductive oxide.

9. The gate pattern of claim 8, wherein the first control gate and the second control gate 239 include polycrystalline silicon.

10. The gate pattern of claim 1, further comprising:
spacers on sidewalls of the gate pattern, wherein the spacers include nitride.

11. A flash memory, comprising:
the gate pattern of claim 1 on a substrate;
a source region in the substrate on a side of the gate pattern; and
a drain region in the substrate and facing the source region with respect to the gate pattern.

12-20. (canceled)
